(19) United States
(12) Patent Application Publication
(10) Pub. No.: US 2026/0068552 A1
(43) Pub. Date: Mar. 5, 2026

(54) CUBIC GAN SEMICONDUCTOR DEVICE MANUFACTURING METHODS

(71) Applicant: Hyperlume Inc., Ottawa (CA)

(72) Inventors: Bilal Janjua, Toronto (CA); Mohsen Asad, Ottawa (CA); Hossein Fariborzi, Auburndale, MA (US)

(73) Assignee: Hyperlume Inc., Ottawa (CA)

(21) Appl. No.: 19/054,863

(22) Filed: Feb. 16, 2025

Related U.S. Application Data
(63) Continuation of application No. PCT/CA2024/051135, filed on Aug. 30, 2024.

(51) Int. Cl. H01L 21/02; C30B 25/18; C30B 29/40; H10D 62/815; H10D 62/824

(52) U.S. Cl. CPC H01L 21/0259; C30B 25/183; C30B 25/186; C30B 29/406; H10D 62/8161; H10D 62/824

(57) ABSTRACT

A method for fabricating a semiconductor device, the method comprising the steps of: providing a silicon-on-insulator (SOI) substrate, the SOI substrate comprising a groove exposing different crystal facing a planar surface; depositing a buffer layer over the substrate; epitaxially growing a semiconductor layer over the buffer layer, whereby least a portion of the buffer layer exhibits a cubic crystalline phase structure.

### FIELD

Aspects of the disclosure relate to methods for manufacturing semiconductor devices based on cubic Group III-N materials.

### BACKGROUND

Group III nitrides consist of nitrogen combined with one or more of the Group III elements from the periodic table, including aluminum (Al), gallium (Ga), and indium (In). These materials have garnered significant interest in the field of optoelectronics, particularly for their applications in portable consumer devices such as handheld projectors, high-resolution televisions, displays, lighting systems and high-speed communication systems.

Among the various Group III nitride materials, Group III nitride micro-LEDs are particularly sought after for their suitability in many portable consumer devices, including handheld projectors, high-resolution televisions, displays, lighting solutions and high-speed communication systems. The lower thermal resistance of micro-LEDs enables operation at higher current densities, leading to increased 3 dB bandwidth and emission efficiency. Additionally, the small footprint of micro-LEDs facilitates the implementation of systems utilizing micro-LED arrays, thereby significantly enhancing throughput.

Significant hurdles persist in the production of GaN-based micro-LEDs, including challenges such as material defects (approximately 10⁹ per cm²) and intrinsic polarization fields (in the range of megavolts per centimeter), causing efficiency losses at elevated bias current densities. GaN epitaxy is typically grown on substrates with high lattice-mismatch, such as sapphire, silicon, or silicon carbide (SiC), resulting in misalignment and asymmetry between the substrate and the GaN regrowth, thus contributing to a heightened occurrence of material defects.

Polarization is an inherent, non-centrosymmetric trait of GaN crystals. In the common growth direction of <0001>, wurtzite (e.g., hexagonal) phase GaN material exhibits characteristic polarity, which adversely affects the recombination characteristics in LEDs due to inefficient recombination across misaligned electron and hole wavefunctions.

Cubic (c-GaN) material holds promise for several potential benefits. One potential advantage of cubic GaN is its high hole mobility, which has been reported to reach 350 cm²/V·s in cubic GaN on GaAs substrates. Additionally, theoretical calculations suggest that Auger recombination in the blue-green region may be smaller in c-GaN structures compared to their wurtzite counterparts, potentially impacting efficiency droop effects.

According to literature, c-GaN has been successfully grown using plasma-assisted molecular beam epitaxy (MBE) or metalorganic vapor phase epitaxy (MOVPE) on various substrates, including 3C SiC, 6H SiC (as a superlattice), GaAs, and Si (001). Furthermore, the growth of nanowires with cubic GaN has been demonstrated using MBE. Notably, in the case of growth on GaAs, large free-standing samples with a thickness of up to 100μm have been achieved. While these achievements are notable, it is generally acknowledged that such prolonged growth processes are not compatible with cost-effective high-volume manufacturing of LEDs.

Structures containing cubic GaInN/GaN multi-quantum wells (MQWs) have been documented on 3C SiC, with photoluminescence (PL) emission observed in the green region. Simple p-GaN/n-GaN junction light-emitting diodes (LEDs) have been described on GaAs substrates. While EL spectra suggests a linear dependency of intensity on drive current, the total light output power from these devices remains undisclosed.

Recently, research has explored short-wavelength devices, with near-ultraviolet emission at 370 nm observed in photoluminescence (EL) from cubic AlGaN/GaN MQWs of varying widths. This emission can be modeled using square-well potentials, suggesting an absence of polarization fields along the (001) direction.

However, it is important to note that the techniques described for growing cubic Group III-N compounds have largely been isolated efforts and have not yet gained widespread acceptance for device fabrication. Many results have shown significant levels of defects, including uncontrolled spatial variations between cubic and hexagonal GaN materials. Hexagonal GaN remains the preferred material for device applications, being the most extensively explored and the sole phase used in today's commercial devices.

The epitaxial growth of high-quality cubic Group III-N compounds at a scale suitable for practical device fabrication remains a challenge. This is partly due to issues like uncontrolled phase mixtures with the hexagonal phase and challenges in selecting substrates for epitaxy, stemming from mismatches in crystal symmetry and lattice constants. While sapphire and SiC have traditionally been used as substrate materials, they are incompatible with mainstream semiconductor technology, which predominantly relies on (100) silicon wafer substrates. Despite silicon's widespread use in microelectronics, it hasn't been extensively explored as a substrate for cubic or hexagonal Group III-N nitrides due to growth challenges and intrinsic absorption in remaining Si post-growth. Successful utilization of Si as a substrate for III-N optical devices would ideally involve a process for substrate material removal before device packaging.

Recent advancements, leveraging large-area nano/micro scale interferometric lithography, have demonstrated the growth of cubic GaN with controllable, symmetry-induced phase separation from the hexagonal phase during growth on deep sub-micron scale (111) silicon-faceted V-grooves fabricated into (100) silicon wafer substrates. This signifies the feasibility of epitaxial growth of cubic Group III-N materials on (100) silicon wafer substrates at the both nano and micron scale, aligning directly with current Si microelectronics technology.

Further progress in the growth of cubic Group III-N materials that address one or more deficiencies of current growth techniques would be a valuable addition to the field of III-N semiconductors.

### SUMMARY

In one of its aspects, a method for fabricating a semiconductor device, the method comprising the steps of:
providing a silicon-on-insulator (SOI) substrate;
etching at least one groove within the SOI substrate to expose a facet in a crystal orientation facing a planar surface;
depositing a buffer layer over the SOI substrate;
depositing a predetermined amount of at least one semiconductor material within the groove;
epitaxially growing a semiconductor layer over the buffer layer, whereby least a portion of the buffer layer exhibits a cubic crystalline phase lattice structure.

In another of its aspects, a method for fabricating a semiconductor device, the method comprising the steps of:
providing a first layer of silicon;
   depositing a second layer of buried oxide;
   depositing a third layer of silicon;
   within the third layer of silicon, etching at least one delineated U-shaped groove with a base portion of the groove comprising of silicon dioxide (SiO₂) and silicon sidewalls angled to the base portion;
   depositing a predetermined amount of at least one semiconductor material within the at least one delineated U-shaped groove;
   depositing a fourth layer of patterned dielectric atop the silicon to define the vertical sidewalls of the at least one delineated U-shaped groove;
   depositing a fifth layer of buffer enveloping both the third and fourth layers;
   depositing a sixth layer of gallium nitride deposited on the buffer layer; and
   epitaxially growing a semiconductor layer over the buffer layer, whereby least a portion of the buffer layer exhibits a cubic crystalline phase lattice structure.

In another of its aspects, a semiconductor device comprising non-polarization material comprising multiple layers, the device comprising:
a silicon-on-insulator (SOI) substrate wafer comprising:
a first layer of silicon;
a second layer of buried oxide;
a third layer of silicon comprising at least one delineated U-shaped groove with a base portion of the groove comprising of silicon dioxide (SiO₂) and silicon sidewalls angled to the base portion;
a fourth layer of patterned dielectric atop the silicon to define the vertical sidewalls of the at least one delineated U-shaped groove;
a fifth layer of buffer enveloping both the third and fourth layers;
a sixth layer of gallium nitride deposited on the buffer layer.

There is provided polarization-free, low-defectivity, multi-wavelength Group-III nitride-based devices and methods for their fabrication. These devices offer a cost-effective alternative to utilizing nonpolar GaN freestanding substrates, as previously mentioned. In addition, these devices overcome the inherent limitation in c-GaN growth on pattered bulk crystalline silicon (100) substrate. While gallium nitride (GaN) material is referenced in the devices, it serves as an example only. The discussions herein are equally applicable to any Group III or other material containing both hexagonal and cubic phases.

The present disclosure offers a solution to the previously mentioned problem by transitioning the material phase from hexagonal to cubic in a well-defined arrangement, effectively addressing polarization effects. The method outlined in this disclosure involves selective area growth of GaN on buffered patterned silicon-on-insulator coated with a dielectric. In various embodiments, this growth technique results in complete surface coverage of cubic-phase GaN (c-GaN) achieved through deliberate deposition of a predetermined amount of GaN, such as depositing GaN within a U-shaped groove etched in silicon-on-insulator substrate. Consequently, the disclosed manufacturing process yields cubic-phase III-Nitride device structure via silicon-on-insulator patterning.

The advantages of utilizing cubic-phase growth in device manufacturing, as outlined in this disclosure, include the capacity to seamlessly integrate Group III nitride materials like GaN with silicon complementary metal-oxide semiconductor (CMOS) materials, which are both widespread and cost-effective. Nevertheless, the growth of GaN on Si (100) typically results in a polycrystalline structure with rough surfaces composed of numerous grains. This outcome arises from the fourfold symmetry of Si (100) substrates and the challenge of achieving preferred orientation alignment for GaN with its odd symmetry on this surface. Although the mismatch values for GaN on Si (100) are lower than those for Si (111), the material quality suffers due to the presence of twist boundaries. Overall, GaN grown on Si (100) tends to exhibit twist boundaries and lower material quality.

In more detail, due to the equivalent crystallographic geometry of the h-crystal in the <001> direction and the c-crystal in the <111> direction, when two h-phase (0001) growth fronts merge at an angle between the two Ga-N bonds in the tetrahedral bonding), a cubic phase forms after the merge between the two growth fronts. Anisotropic patterning of a Si (100) substrate can be utilized to create U-shaped grooves with a crystallographic angle of 54.74 degrees between the Si (100) and the Si (111) surface. Buried oxide acts as a n etch stop layer and accurately defines the depth of these grooves, an important parameter in the eventual realization of complete device structures based on good quality cubic phase. Consequently, selective metalorganic chemical vapor deposition (MOCVD) growth of GaN on the silicon sidewalls of the U-groove leads to two h-GaN growth fronts meeting at an angle of 54.74 degrees×2=109.5 degrees, facilitating the transition from h-GaN into c-GaN after coalescence (or merge). This coalescence occurs when the two h-GaN growth fronts meet.

Furthermore, the emission wavelength of the cubic GaN phase LED structure can be manipulated by altering all the relevant dimensions of the grooves in a controllable fashion. Several factors contribute to this phenomenon such as the current crowding effect varies with different chip sizes, leading to a deviation from the predicted red shift at different current densities in the quantum well (QW. Secondly, in high indium QWs, the presence of large random alloy fluctuations or indium segregation is expected, resulting in a non-uniform filling of states compared to ideal scenarios. Lastly, although compressive InGaN is relaxed the top multi-QWs of InGaN still endure compressive strain, contributing to the wavelength shift due to a combination of factors including the screening of quantum-confined Stark effect (QCSE), quantum effects, and band filling. This multiwavelength emission capability enables the utilization of complex communication schemes such as Wavelength Division Multiplexing (WDM) that leverages multiple light wavelengths (or colors) to transmit data over the same medium simultaneously. This technique holds significant advantages for high-speed communication systems.

### BRIEF DESCRIPTION OF THE DRAWINGS

Several exemplary embodiments of the present disclosure will now be described, by way of example only, with reference to the appended drawings in which:

FIG. 1A shows a cross-sectional view of a patterned substrate;

FIG. 1B shows a cross-sectional view of buffer layer deposited selectively;

FIG. 2A shows a semiconductor material deposited resulting in formation of cubic gallium nitride;

FIG. 2B shows growth of nonpolar cubic phase quantum wells have varying bandgap;

FIG. 2C shows cubic phase quantum wells grown in various structural configurations;

FIG. 3A shows a contact to p-doped semiconductor;

FIG. 3B shows bonding device structure to a carrier substrate with removed buried oxide and substate;

FIG. 3C shows a contact to n-doped semiconductor;

FIG. 3D shows a device structure with multilayers dielectric on the n and p doped semiconductor;

FIG. 3E shows removal of a carrier substrate;

FIG. 4A shows bonding of device pads to CMOS chip having emission from n doped side;

FIG. 4B shows bonding of device pads to CMOS chip having emission from p doped side; and

FIG. 4C shows a device having enhanced emission and heat dissipation in presence of metal surrounding the device.

### DESCRIPTION

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Moreover, it should be appreciated that the particular implementations shown and described herein are illustrative of the invention and are not intended to otherwise limit the scope of the present invention in any way. Indeed, for the sake of brevity, certain sub-components of the individual operating components, conventional data networking, application development and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

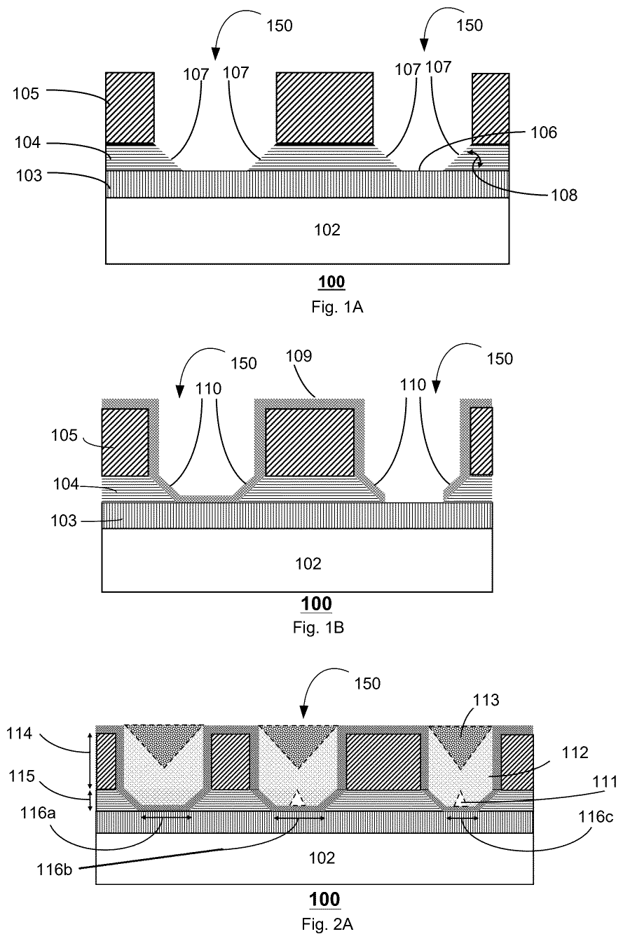

With reference to the FIG. 1A, there is shown a semiconductor device 100 comprising silicon-on-insulator (SOI) substrate 102, buried insulator 103, exposed facet 107 of silicon 104, insulator 105, and insulator 106. The SOI substrate 101 comprises one or more grooves 150. In one example, the groove 150 can take on any form that yields faceted surfaces 111 conducive to the epitaxial crystal growth of the buffer layer. In one example, a V-groove 150 or a flat-bottomed groove 150 can be etched into a silicon or GaAs substrate 102 to ensure Si (111) faceted sidewalls. The exposed facet 107 may comprise <111> a crystal orientation. In one example, to expose the facet 107, a selective chemical process may be used comprising an etchant, such as KOH, TMAH and etc. The angle 108 may be tuned by the chemistry of the etchant, process temperature or other process parameters. In one example, the angle may be 54.7 degree or any other angle based on the optical requirements and material utilized ensuring ensure faceted sidewalls 111. Insulator surface 106 acts as etch stop layer and defines U-groove 150 depth. The design may include an isotropic dry etch followed by KOH etch to obtain a trapezoid profile.

In FIG. 1B, there is shown a semiconductor device 100 fabricated comprising deposition of a buffer 109 such as aluminium nitride (AlN) or aluminium silicide (AlSi) over the patterned insulator and the etched, U-shaped grooves 150. The buffer 109 may or may not bury the patterned dielectric (104) or exposed isolator surface 103. The buffer layer 109 if made up of cubic III-nitride material has an orientation denoted by 110 in (0001) c-direction.

The buffer layer 109 plays a role in ensuring the success of the overall growth process, by serving as a strain relief layer, enhancing the crystal quality of the resulting cubic III-nitride material. Moreover, buffer layer 109 aids in reducing or preventing alloying of the subsequently formed crystal layer 104 with substrate material. For instance, the epitaxial growth of GaN on silicon substrates has demonstrated issues with Ga—Si alloying, know as melt-back etching effect.

To address alloying concerns, buffer layer 109 can be adequately thickened. However, excessive thickness may lead to buffer layer cracking. In one scenario, the thickness of the buffer layer may range from few nanometers to approximately 1 μm. The buffer layer 109 can also comprise of two or more layers with one or more different AlGaN compositions having stepped or graded concentrations.

Various epitaxial growth methods can be employed to fabricate the buffer layer. Examples of suitable methods encompass Molecular Beam Epitaxy (MBE) and Metalorganic Vapor Phase Epitaxy (MOVPE). However, it is worth noting that each MOVPE reactor system exhibits slight variations, leading to potential differences in optimal growth conditions on Si (111) faceted sidewalls of the groove 150. The parameter space for MOVPE can be extensive, considering the myriad combinations of temperature, pressure, gas flows, and layer compositions that are feasible.

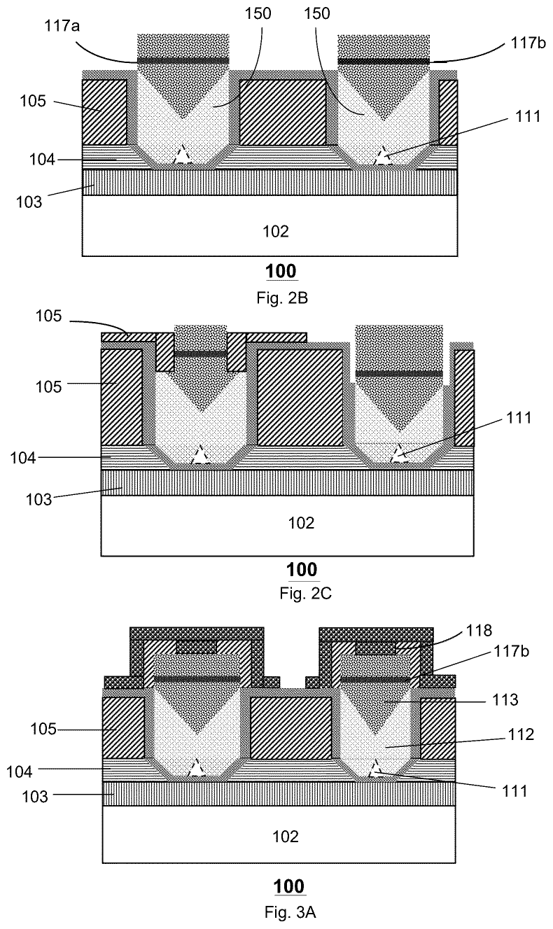

In FIG. 2A, there is shown a semiconductor device 100 fabricated comprising deposition of a semiconductor material e.g. GaN as provided by way of example herein, with in U-shaped groove 150. Note that, during deposition, h-GaN 112 grows off the angled buffer oriented in c-direction (0001) with the U-shaped grooves 150 and combines at merged growth fronts in the middle of the U-shaped grooves 150 at about an angle of 109.5 degree, at the location of intersection or merging of these growth fronts the h-GaN walls turn into cubic GaN 113 (c-GaN) gradually building more c-GaN area as the h-GaN reduces and becomes buried.

In the overlap region, the two c-axes directions cannot coexist without giving rise to a heavily defected region as the material grows upwards from the two sides of the V-groove 150. The inherent symmetry of the Si substrate drives a phase segregation process, resulting in the formation of the c-GaN (or c-InGaN) material in or near the center of the V-groove 150 where the growth regimes overlap. The lattice constant of the c-GaN (or c-InGaN) maybe fully relaxed and is not constrained by the underlying Si lattice constant.

Underneath this intersection point a void 111 may or may not form as determined by growth conditions and material used. With full control over the dielectric height 114 from Si substrate surface 102, silicon-on-insulator thickness 115, and pattern opening 116, the thickness of GaN required to completely cover the underlying h-GaN and may avoid under or overgrowth can be determined. The length 116a and width 116b, 116c of the groove 150, may span from a few nanometers to accommodate the formation of the cubic lattice region up to any width feasible. In one scenario, 116 can be chosen to be comparable with the diffusion length of a Ga adatom under the epitaxial growth conditions, typically several microns or less. The length 116a and width 116b of the groove 150 may have similar or different lengths.

Additional examples of appropriate cubic III-nitride materials comprise InGaN, AlGaNInN, GaAsSbN, InAlAsN, InGaAsN, and AlGaN. Furthermore, other cubic III-V materials are viable, including GaAs, AlGaAs, or InGaAs.

In FIG. 2B, there is shown a semiconductor device 100 comprising deposition of a group III-nitride material e.g. InGaN 117a as provided by way of example herein, outside U-shaped groove 150 followed by c-GaN. Note that, InGaN acquires cubic phase from underlying c-GaN and being a smaller bandgap material thus forms a quantum well structure which determines emission wavelength. The structure can be modified to epitaxially grown MQW structure having presence of alternating layers consisting of thicker c-GaN and thinner c-InGaN, forming quantum wells. The utilization of alternating layers to create quantum wells is a widely recognized technique in the field. Alternative layers can consist of any compatible semiconductor material system which fulfill the criterial of forming quantum well system.

Epitaxial layers 12, 13 and 17 can be cultivated using any appropriate method, including molecular beam epitaxy (MBE) or metalorganic vapor phase epitaxy (MOVPE). The chosen method may coincide with or differ from the epitaxial technique utilized for growing the buffer layer 109. Various source materials can be utilized, depending on the specific requirements. For instance, in the context of forming InGaN, any suitable gallium, nitrogen, and indium source materials may be employed. The selection of suitable source materials for both MBE and MOVPE processes is well-established within the field.

In one embodiment, multiple epitaxially grown cubic layers can be simultaneously cultivated within numerous adjacent grooves 150. Each of these epitaxial layers may encompass both hexagonal and cubic phase lattice structures, such as c-GaN/c-InGaN regions and h-GaN/h-InGaN regions. Consequently, the resultant epitaxially grown layers may consist of several distinct multiple quantum well (MQW) cubic regions that are separated from each other. Depending on the chosen dimensions 114, 115, 116a and 116b, the composition of c-InGaN may vary.

The quantum-well active region, along with the p-GaN and n-GaN layers, can be established within a single GaN growth sequence. Alternatively, the wafer featuring cubic GaN can be patterned initially, followed by the utilization of a growth mask to selectively re-grow the cubic GaN active region solely on the exposed cubic GaN regions. Using patterned mask and multi growth steps, quantum wells of different compositions 117a and 117b can be realized.

In FIG. 2C, there is shown a semiconductor device 100 fabricated based on a standard lithography process pattern opening made on top of U-groove 150 having freshly deposited insulator later. The openings which are smaller than the groove 150 result in freshly deposited dielectric covering the inner sidewalls. To achieve these continuous films, a growth mask containing materials such as SiO2 can be utilized. This mask selectively allows the growth of the cubic phase, thus aiding in preventing the formation of mixed phases during the growth of c-GaN. Once the growth of h-GaN is halted, subsequent layers including the InGaN quantum wells (QWs) can be introduced. Following this, the growth process can either proceed until coalescence is achieved or a segmented device can be constructed. Another potential issue arises from the h-InGaN quantum wells positioned adjacent to the c-InGaN wells, which may offer a lower energy level can be mitigated. This could prevent siphoning of carriers away from the c-InGaN wells resulting in higher internal quantum efficiency. In another example, where the openings are bigger, the insulator layer 105 sidewall can be etched to remove unwanted grown material, then the subsequent layers including quantum wells are grown. Growth conditions are optimized to ensure absence of mixed phase.

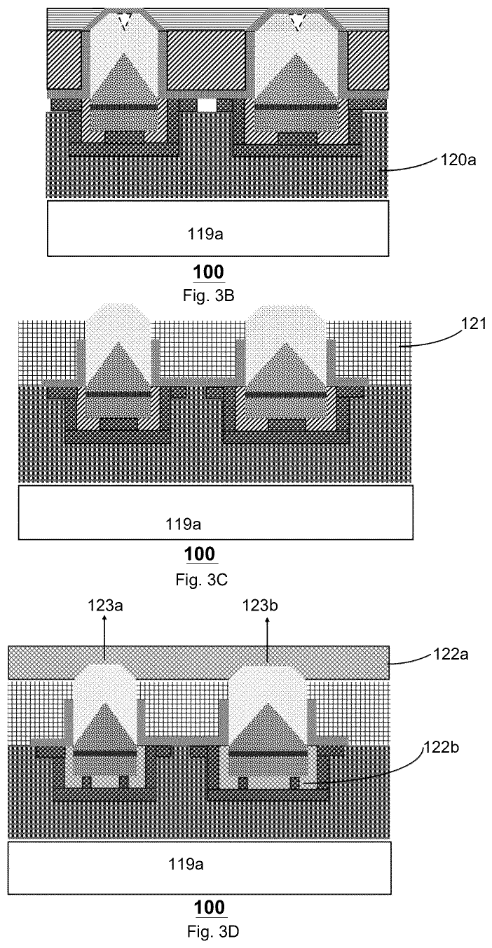

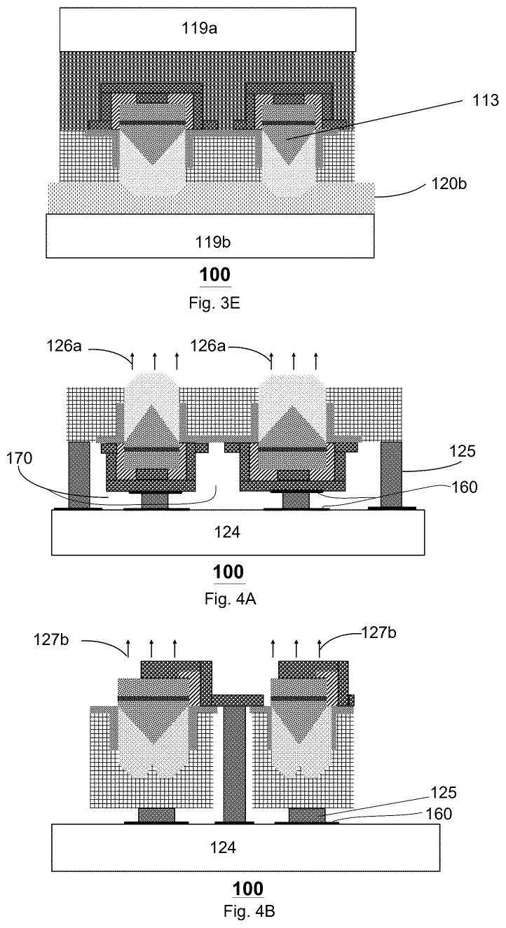

In FIG. 3A, there is shown a semiconductor device 100 fabricated comprising deposition of metal contact 118 which may consist of chromium, gold, nickel-gold, palladium-nickle-gold, nickel-indium tin oxide or any other metal scheme compatible with semiconductors. This allows injection of holes into the device structure.

Regions 112, 113, and 117a, b can undergo doping to establish heterojunction(s), a well-known technique in the field, thereby enabling the functionality of a light emitting diode.

The individual cubic regions can then be electrically interconnected either in parallel, series, or any hybrid configuration. In numerous electronics and optics applications, it may be beneficial to link multiple adjacent nanowires in parallel to enhance the current-carrying capacity. Moreover, certain electronics applications may necessitate an alternative electrical arrangement, mirroring the common practice seen in modern integrated circuits. top contact can be a transparent conductive oxide or a semi-transparent metal.

The cubic phase epitaxial layers described in this disclosure can find utility in a diverse array of semiconductor devices. Examples of such devices include light-emitting diodes (LEDs), laser diodes, photodetectors etc.

In FIG. 3B, there is shown a semiconductor device 100 fabricated comprising first edge trimming to facilitate the wafer bonding process with a carrier substrate 119a via a suitable adhesive 120a, such as, benzocyclobutene (BCB), among others.

Retaining the Si substrate 119 can pose challenges for LEDs due to its strong visible absorption and lack of access to the n-GaN 112 and 113. In such cases, removing the silicon substrate 119 may be preferable. For instance, the sample can be bonded to a new handle substrate, which could be transparent, non-transparent, or reflective. Subsequently, the Si substrate 119 can be selectively removed using an appropriate method including mechanical griding/lapping, dry or wet etching processes.

Micro-transfer printing technology can also be adopted in transferring the microLEDs with high throughput and high accuracy by using the buried oxide as the release layer, for example, by complete removal of the buried insulator 103 using a polishing, wet etching or dry etching process; thereby exposing the buffer layer 109.

In FIG. 3C, there is shown a semiconductor device 100 fabricated comprising removing partially buffer layer 109 using polishing, wet or dry etching process. This is done to expose the n doped semiconductor layer of the envisioned devices. The method comprises completely removing layer 104 using wet etching or dry etching process.

Following that a metal layer 121 such as aluminum to form n-contact to inject electron in the device structure is deposited. In case of n-doped GaN, metal layer may consist of multiple layers such titanium, aluminum, nickel, gold to form an ohmic contact followed by a thick aluminum layer. The deposition can be blanket or patterned.

In FIG. 3D, there is shown a semiconductor device 100 fabricated comprising deposition of multi-layer dielectric layer 122a and 122b. These layers can be designed to be distributed Bragg reflector to allow resonant cavity lasing action with narrow emission wavelengths 123a and 123b determined by the groove 150 size and quantum well compositions. Layer 122a can also be used for surface passivation to reduce indirect carrier recombination at quantum well sidewall. Furthermore, layer 122b can be used to provide an index matching material interface at semiconductor air interface to enhance light extraction from light emitting device.

In FIG. 3E, there is shown a semiconductor device 100 comprising bonding of metal 121 onto a carrier substrate 122 having metal or any conducting material such graphene, transparent conductive oxide. The semiconductor device 100 is fabricated comprising a step of dismounting of carrier substrate 119a. The silicon substrate 119a has a high absorption coefficient in the visible spectrum and needs to be removed to achieve increased emission. As such, the method may comprise dismounting of carrier substrate 119a by first bonding carrier substrate 119a onto another carrier substrate 119b with an adhesive 120b.

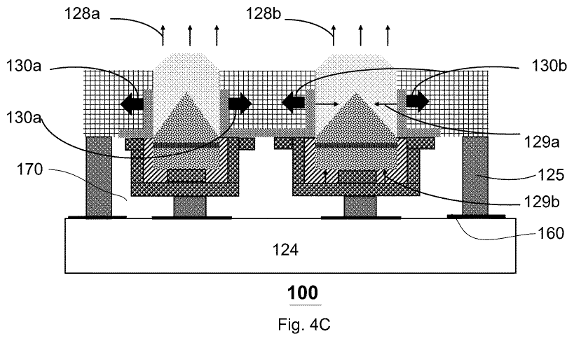

In FIG. 4A, there is shown a semiconductor device 100 fabricated comprising removal of adhesive layer 120 and carrier substrate 119. Shown is a mounted flip chip optical device structure of the present invention. The flip chip embodiment of FIG. 4A includes an interconnect CMOS board 124 of the type known to those skilled in the art of electrical connection of the LED. The process requires precise alignment over the substrate to ensure the solder bumps 125 are aligned with the contact pads on the substrate. The flip chip LED structure provides access to the light path. Following flip chip bonding carrier substrate 119b and adhesive 120b are removed.

In FIG. 4B, there is shown a semiconductor device 100 fabricated comprising another depiction of envisioned device with both contacts. Beginning with the creation of contact pads 160 on both the CMOS chip and substrate, often referred to as bump bond metallization, several methods such as sputtering, vapor deposition, or electroplating can be utilized for their deposition. This metallization facilitates efficient electrical contact and provides a surface suitable for a molten solder alloy. Subsequently, solder bumps can be formed on the contact pad located on the chip's relevant surface, employing various growth techniques, with electroplating being the predominant method. The process requires precise alignment over the substrate to ensure the bumps are aligned with the contact pads on the substrate. Following remelting and soldering, the gaps 170 are filled with eclectically insulating adhesive. Thermal compression bonding is an alternative.

In FIG. 4C, upon completion of the fabrication method the device structure can be electrical current biased. Light is collected from the top side or bottom side of the device. The emission wavelength may vary depending on the size of the U-groove structure and the composition of the quantum well. Metal layer 121 surrounding the bottom may act as a thermal heat sink while also providing light reflection. For microLEDs working at higher current densities better heat dissipation results in reduced thermal droop and improved light extraction efficiency.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Accordingly, the above description of example implementations does not define or constrain this disclosure. Other changes, substitutions, and alterations are also possible without departing from the spirit and scope of this disclosure.

1. A method for fabricating a semiconductor device, the method comprising the steps of:
providing a silicon-on-insulator (SOI) substrate;
etching at least one groove within the SOI substrate to expose a facet in a crystal orientation facing a planar surface;
depositing a buffer layer over the SOI substrate;
depositing a predetermined amount of at least one semiconductor material within the groove;
epitaxially growing a semiconductor layer over the buffer layer, whereby at least a portion of the buffer layer exhibits a cubic crystalline phase lattice structure.

2. The method of claim 1, wherein the at least one groove comprises a depth defined by the crystalline silicon thickness on the SOI substrate.

3. The method of claim 2, wherein the at least one groove comprises a depth defined by a lithography process.

4. The method of claim 1, wherein the at least one groove comprises a depth defined by the crystalline silicon thickness having buried oxide as each stop layer.

5. The method of claim 1, wherein at least one groove yields Si (111)-faceted surfaces.

6. The method of claim 5, wherein the at least one groove is V-shaped.

7. The method of claim 5, wherein the at least one groove is U-shaped.

8. The method of claim 1, wherein the buffer layer comprises at least two layers, and selecting a thickness of the buffer layer to minimize alloying of the grown semiconductor layer, and to minimize cracking of the buffer layer.

9. The method of claim 8, wherein the thickness of the buffer layer ranges from 2 nm to 1 μm.

10. The method of claim 9, wherein the buffer layer comprises at least one material chosen from AlN, GaN, or Al(x)Ga(1−x)N, where x ranges from zero to one.

11. The method of claim 1, wherein a plurality of epitaxially grown cubic layers are simultaneously cultivated within a plurality of adjacent at least one groove.

12. The method of claim 11, wherein the plurality of epitaxially grown cubic layers may encompass both hexagonal and cubic phase lattice structures.

13. The method of claim 12, wherein the plurality of epitaxially grown cubic layers comprise a plurality of distinct multiple quantum well (MQW) cubic regions that are separated from each other.

14. A method for fabricating a semiconductor device, the method comprising the steps of:
providing a first layer of silicon;
depositing a second layer of buried oxide;
depositing a third layer of silicon;
within the third layer of silicon, etching at least one delineated U-shaped groove with a base portion of the groove comprising of silicon dioxide (SiO₂) and silicon sidewalls angled to the base portion;
depositing a predetermined amount of at least one semiconductor material within the at least one delineated U-shaped groove;
depositing a fourth layer of patterned dielectric atop the silicon to define the vertical sidewalls of the at least one delineated U-shaped groove;
depositing a fifth layer of buffer enveloping both the third and fourth layers;
depositing a sixth layer of gallium nitride deposited on the buffer layer; and
epitaxially growing a semiconductor layer over the buffer layer, whereby least a portion of the buffer layer exhibits a cubic crystalline phase lattice structure.

15. The method of claim 14, wherein the sixth layer comprises cubic gallium nitride (c-GaN) merged with a frontal aspect of hexagonal gallium nitride (h-GaN) extending from the silicon sidewall.

16. The method of claim 15, wherein the cubic gallium nitride (c-GaN) comprises a deposition thickness (h) of gallium nitride over the third layer of silicon sufficient for complete coverage of h-GaN by c-GaN between the sidewalls.

17. The method of claim 14, wherein the buffer layer comprises at least one material chosen from AlN, GaN, or Al(x)Ga(1−x)N, where x ranges from zero to one.

18. The method of claim 14, wherein a plurality of epitaxially grown cubic layers are simultaneously cultivated within a plurality of adjacent at least one delineated U-shaped groove.

19.-25. (canceled)
